(19) United States
(12) Patent Application Publication
(10) Pub. No.: US 2025/0226185 A1
(43) Pub. Date: Jul. 10, 2025

(54) SUBSTRATE PROCESSING METHOD AND SUBSTRATE PROCESSING APPARATUS

(71) Applicant: Tokyo Electron Limited, Tokyo (JP)

(72) Inventors: Kazuki MOYAMA, Miyagi (JP); Michishige SAITO, Miyagi (JP)

(73) Assignee: Tokyo Electron Limited, Tokyo (JP)

(21) Appl. No.: 19/091,912

(22) Filed: Mar. 27, 2025

Related U.S. Application Data
(63) Continuation of application No. PCT/JP2023/034066, filed on Sep. 20, 2023.

(30) Foreign Application Priority Data
Sep. 29, 2022 (JP) 2022-156507

(51) Int. Cl. H01J 37/32; H01L 21/66

(52) U.S. Cl. CPC H01J 37/32449; H01L 22/26; H01J 2237/334

(57) ABSTRACT

A substrate processing method for processing a substrate by supplying a gas from a gas supply part to a substrate processing space in a substrate processing apparatus, wherein the gas supply part includes a plurality of gas sources, a flow path that allows the gas to flow from the plurality of gas sources to the substrate processing space, a valve provided in the flow path to switch between opening and closing the flow of the gas, and a buffer tank provided in the flow path, pulse control is performed to pulse the flow of the gas by alternately repeating the opening and closing of the flow of the gas in the valve, and in the pulse control, a duration of the pulse control and a number of times of opening the flow of the gas during the duration are controlled to control the flow rate of the gas.

### CROSS-REFERENCE TO RELATED APPLICATIONS

This application is a bypass continuation application of International Application No. PCT/JP2023/034066 having the international filing date of Sep. 20, 2023, and designating the United States, the International Application being based upon and claiming the benefit of priority from Japanese Patent Application No. 2022-156507 filed on Sep. 29, 2022, the entire contents of each are incorporated herein by reference.

### TECHNICAL FIELD

The present disclosure relates to a substrate processing method and a substrate processing apparatus.

### BACKGROUND

Japanese Laid-open Patent Publication No. 2015-144249 discloses a gas supply method for switching two or more types of processing gases in a etching apparatus for a semiconductor substrate. In the gas supply method, the gas supply pulsates by way of switching a path for supplying a gas to a substrate processing space and a path for exhausting a gas using an exhaust system by opening and closing a valve.

### SUMMARY

The technique of the present disclosure reduces gas waste during substrate processing and simplifies a substrate processing apparatus.

According to an exemplary embodiment, a substrate processing method is provided. The substrate processing method for processing a substrate by supplying a gas from a gas supply part to a substrate processing space in a substrate processing apparatus, wherein the gas supply part includes a plurality of gas sources, a flow path that allows the gas to flow from the plurality of gas sources to the substrate processing space, a valve provided in the flow path to switch between opening and closing the flow of the gas, and a buffer tank provided in the flow path, pulse control is performed to pulse the flow of the gas by alternately repeating the opening and closing of the flow of the gas in the valve, and in the pulse control, a duration of the pulse control and a number of times of opening the flow of the gas during the duration are controlled to control the flow rate of the gas.

### BRIEF DESCRIPTION OF THE DRAWINGS

FIG. 1 is an explanatory diagram showing an example of a configuration of a plasma processing system according to an embodiment.

FIG. 2 is a cross-sectional view showing an example of a configuration of a plasma processing apparatus according to an embodiment.

FIG. 3 is a plan view showing an example of a configuration of an upper baffle plate according to an embodiment.

FIG. 4 is a plan view showing an example of a configuration of a lower baffle plate according to an embodiment.

FIG. 5 is a plan view showing an example of arrangement of the upper baffle plate and the lower baffle plate.

FIG. 6 is a side view showing an example of gas flow during exhaust through the upper baffle plate and the lower baffle plate.

FIG. 7 is an explanatory diagram showing an example of a configuration of a plasma processing system according to an embodiment.

FIG. 8 is an explanatory diagram schematically showing pulse control in a substrate processing method according to an embodiment.

FIG. 9 is a flowchart schematically showing a substrate processing method according to an embodiment.

FIG. 10 is an explanatory diagram schematically showing pulse control in a substrate processing method according to another embodiment.

FIG. 11 is a flowchart schematically showing a substrate processing method according to another embodiment.

FIG. 12 is a schematic diagram showing an outline of a conventional gas supply system.

FIG. 13 is a diagram showing an outline of opening and closing control of a valve when a gas is supplied using the conventional gas supply system.

### DETAILED DESCRIPTION

In a manufacturing process of semiconductor devices, a substrate processing space accommodating a semiconductor wafer (hereinafter referred to as “substrate”) is depressurized, and various processing steps are performed to perform predetermined processing on the substrate. Gas processing is performed in such processing steps.

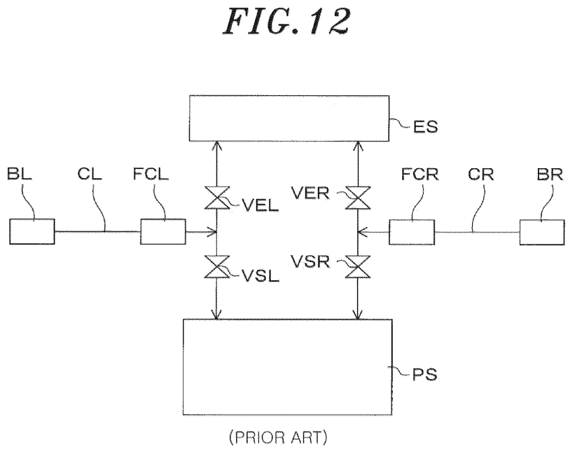

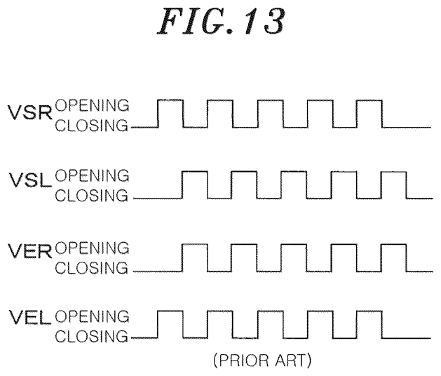

In semiconductor dry processing as the predetermined processing performed in the substrate processing apparatus, two or more types of processing gases may be repeatedly switched at a high speed. For example, Japanese Laid-open Patent Publication No. 2015-144249 discloses a device for switching between a path for supplying a gas to a substrate processing space and a path for disposing a gas using an exhaust system, by exclusively controlling a valve. Specifically, a gas supply system shown in FIG. 12 is adopted.

FIG. 12 is a schematic diagram showing an outline of a conventional gas supply system that enables switching between two or more types of gases by the method disclosed in Japanese Laid-open Patent Publication No. 2015-144249. The conventional gas supply system includes a gas box BR that supplies one mixed gas GR and a gas box BL that supplies another mixed gas GL. The gas boxes BR and BL are connected to flow paths CR and CL, respectively. The flow paths CR and CL are equipped with flow rate controllers FCR and FCL, respectively. The flow path CR branches into an exhaust flow path ER connected to an exhaust system ES and a supply flow path SR connected to a substrate processing space PS. The flow path CL branches into an exhaust flow path EL connected to the exhaust system and a supply flow path SL connected to the substrate processing space PS. The exhaust flow paths ER and EL are equipped with exhaust valves VER and VEL, respectively, and the supply flow paths SR and SL are equipped with supply valves VSR and VSL, respectively.

FIG. 13 is a diagram showing an outline of opening and closing control of a valve when a gas is supplied using the conventional gas supply system shown in FIG. 12. In the conventional gas supply system, in the case of supplying one mixed gas GR and another mixed gas GL separately and alternately, when one mixed gas GR is supplied, the exhaust valve VER and the supply valve VSL are closed, and the supply valve VSR and the exhaust valve VEL are opened. Accordingly, one mixed gas GR is supplied to the substrate processing space PS, and another mixed gas GL is discharged by the exhaust system ES. When another mixed gas GL is supplied, the exhaust valve VEL and the supply valve VSR are closed, and the supply valve VSL and the exhaust valve VER are opened. Accordingly, another mixed gas GL is supplied to the substrate processing space PS, and one mixed gas GR is discharged by the exhaust system ES. By repeating this alternately, one mixed gas GR and another mixed gas GL are separately and alternately supplied to the substrate processing space PS.

When the flow rate is changed by the flow rate controllers FCR and FCL, time is required until the flow rate is stabilized. Specifically, a response time of about 500 ms is required until the flow rate is stabilized, which is slow and not practical in view of high-speed processing. Hence, in the gas supply system of Japanese Laid-open Patent Publication No. 2015-144249, the switching time is shortened by switching the mixed gases without changing the flow rate. In the case of using such a gas switching mechanism, it is possible to shorten the switching time. However, the gas that is not supplied to the substrate processing space PS needs to be constantly disposed, which is uneconomical. In addition, in order to obtain a desired flow rate of the gas to be supplied to the substrate processing space PS, the flow rate controllers FCR and FCL installed at the downstream sides of the gas boxes BR and BL are necessary for the reasons to be described below. Therefore, the size of the entire gas supply system needs to be increased by the amount of the flow rate controller. Further, “the size of the system” includes the structural complexity of the system as well as the simple occupied area (volume).

Therefore, in the technique of the present disclosure, the gas supply is performed using a pulse-controllable valve, thereby eliminating the need for constant gas disposal during gas switching and minimizing gas disposal. In addition, by eliminating the need for a flow rate controller that was required for each gas at the downstream side of the gas box in the conventional gas supply system, the gas supply part and further the substrate processing apparatus are simplified. Further, “simplifying” the gas supply part and the substrate processing apparatus includes reducing the occupied area (volume) and/or simplifying the structure relatively compared to the prior art.

Hereinafter, the configuration of the substrate processing system according to the present embodiment will be described with reference to the accompanying drawings. Further, in this specification, like reference numerals will be used for like parts having substantially the same functions and configurations, and redundant description thereof will be omitted.

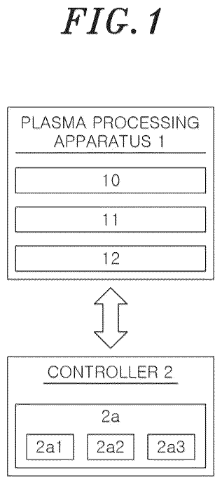

FIG. 1 is a diagram for explaining an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a substrate processing space 10s. In addition, the plasma processing chamber 10 has at least one gas supply port for supplying at least one processing gas to the substrate processing space 10s and at least one gas exhaust port for exhausting a gas from the substrate processing space 10s. The gas supply port is connected to a gas supply part 20 to be described later, and the gas exhaust port is connected to an exhaust system 40 to be described later. The substrate support 11 is located in the substrate processing space 10s, and has a substrate supporting surface for supporting a substrate.

The plasma generator 12 is configured to produce plasma from at least one processing gas supplied into the substrate processing space 10s. The plasma produced in the substrate processing space 10s may be capacitively coupled plasma (CCP), inductively coupled plasma (ICP), electron-cyclotron-resonance plasma (ECR plasma), helicon wave plasma (HWP), or surface wave plasma (SWP). Further, various types of plasma generators including an alternating current (AC) plasma generator and a direct current (DC) plasma generator may be used. In one embodiment, the AC signal (AC power) used in the AC plasma generator has a frequency within the range of 100 kHz to 10 GHz. Therefore, the AC signal includes a radio frequency (RF) signal and a microwave signal. In one embodiment, the RF signal has a frequency within the range of 100 kHz to 150 MHz.

The controller 2 processes computer-executable instructions that cause the plasma processing apparatus 1 to perform various steps described in the present disclosure. The controller 2 may be configured to control individual components of the plasma processing apparatus 1 to perform various steps described herein. In one embodiment, the controller 2 may be partially or entirely included in the plasma processing apparatus 1. The controller 2 may include a processing part 2a1, a storage part 2a2, and a communication interface 2a3. The controller 2 is realized by, for example, a computer 2a. The processing part 2a1 may be configured to read a program from the storage part 2a2 and execute the read program to perform various control operations. The program may be stored in the storage part 2a2 in advance, or may be acquired via a medium when necessary. The acquired program is stored in the storage part 2a2, and is read from the storage part 2a2 and executed by the processing part 2a1. The medium may be various storage media that are readable by the computer 2a, or may be a communication line connected to the communication interface 2a3. The processing part 2a1 may be a central processing unit (CPU). The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

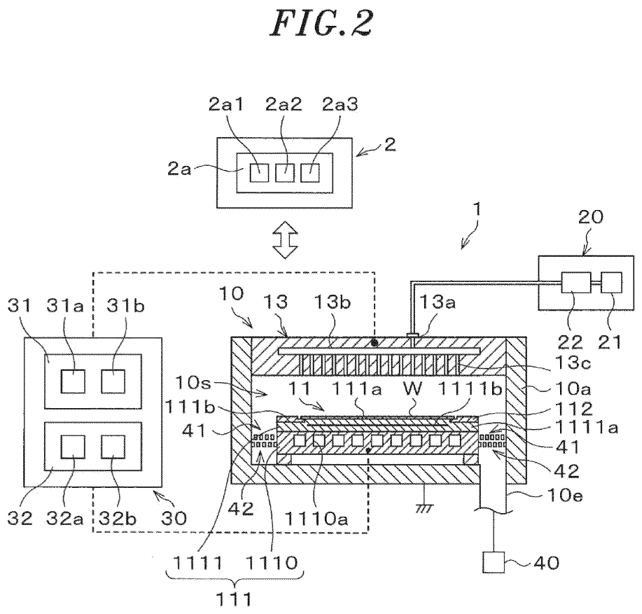

Hereinafter, an example of a configuration of a capacitively coupled plasma processing apparatus 1 as an example of a substrate processing apparatus will be described. FIG. 2 is a diagram for explaining an example of a configuration of the capacitively coupled plasma processing apparatus 1.

The capacitively coupled plasma processing apparatus 1 includes the plasma processing chamber 10, the gas supply part 20, a power supply part 30, and the exhaust system 40. Further, the plasma processing apparatus 1 includes the substrate support 11 and a gas introducing part. The gas introducing part is configured to introduce at least one processing gas into the plasma processing chamber 10. The gas introducing part includes a shower head 13. The substrate support 11 is located in the plasma processing chamber 10. The shower head 13 is located above the substrate support 11. In one embodiment, the shower head 13 constitutes at least a part of the ceiling of the plasma processing chamber 10. The plasma processing chamber 10 has the substrate processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting the substrate W and an annular region 111b for supporting the ring assembly 112. The annular region 111b of the main body 111 surrounds the central region 111a of the main body 111 in plan view. The substrate W is located on the central region 111a of the main body 111, and the ring assembly 112 is located on the annular region 111b of the main body 111 to surround the substrate W on the central region 111a of the main body 111. Therefore, the central region 111a is also referred to as a substrate supporting surface for supporting the substrate W, and the annular region 111b is also referred to as a ring supporting surface for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is located on the base 1110. The electrostatic chuck 1111 includes a ceramic member 1111a and an electrostatic electrode 1111b located in the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be located on either the annular electrostatic chuck or the annular insulating member, or may be located on both the electrostatic chuck 1111 and the annular insulating member. Further, at least one RF/DC electrode connected to a radio frequency (RF) power supply 31 and/or a DC power supply 32, which will be described later, may be located in the ceramic member 1111a. In this case, at least one RF/DC electrode functions as a lower electrode. When a bias RF signal and/or a DC signal to be described later is supplied to at least one RF/DC electrode, the RF/DC electrode is also referred to as a bias electrode. Further, the conductive member of the base 1110 and at least one RF/DC electrode may function as a plurality of lower electrodes. Further, the electrostatic electrode 1111b may function as a lower electrode. Thus, the substrate support 11 includes at least one lower electrode.

The ring assembly 112 includes one or multiple annular members. In one embodiment, one or multiple annular members include one or multiple edge rings and at least one cover ring. The edge ring is made of a conductive material or an insulating material, and the cover ring is made of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid such as brine or a gas flows through the flow path 1110a. In one embodiment, the flow path 1110a is formed in the base 1110, and one or multiple heaters are located in the ceramic member 1111a of the electrostatic chuck 1111. Further, the substrate support 11 may include a heat transfer gas supply configured to supply a heat transfer gas to a gap between the backside of the substrate W and the central region 111a.

The shower head 13 is configured to introduce at least one processing gas from the gas supply part 20 into the substrate processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the substrate processing space 10s from the plurality of gas inlet ports 13c. Further, the shower head 13 includes at least one upper electrode. The gas introducing part may include, in addition to the shower head 13, one or multiple side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one processing gas from the corresponding gas source 21 to the shower head 13 via the corresponding flow rate controller 22. The flow rate controllers 22 may include, e.g., a mass flow controller or a pressure-controlled flow rate controller. Further, the gas supply part 20 may include at least one flow rate modulation device for modulating the flow rate of at least one processing gas or causing it to pulsate. In this specification, the gas source is described as the upstream side of the gas flow, and the substrate processing space 10s is described as the downstream side thereof. The gas supply part 20 and the substrate processing space 10s will be described in detail later.

The power supply part 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is produced formed from at least one processing gas supplied to the substrate processing space 10s. Thus, the RF power supply 31 can function as at least a part of the plasma generator 12. In addition, by supplying a bias RF signal to at least one lower electrode, a bias potential is generated at the substrate W, and ion components in the produced plasma can be attracted to the substrate W.

In one embodiment, the RF power supply 31 includes a first RF generator 31a and a second RF generator 31b. The first RF generator 31a is connected to at least one lower electrode and/or at least one upper electrode via at least one impedance matching circuit, and is configured to generate a source RF signal (source RF power) for plasma generation. In one embodiment, the source RF signal has a frequency within the range of 10 MHz to 150 MHz. In one embodiment, the first RF generator 31a may be configured to generate a plurality of source RF signals having different frequencies. The generated one or multiple source RF signals are supplied to at least one lower electrode and/or at least one upper electrode.

The second RF generator 31b is connected to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within the range of 100 KHz to 60 MHz. In one embodiment, the second RF generator 31b may be configured to generate a plurality of bias RF signals having different frequencies. The generated one or multiple bias RF signals are provided to at least one lower electrode. Further, in various embodiments, at least one of the source RF signal and the bias RF signal may pulsate.

Further, the power supply part 30 may include a DC power supply 32 connected to the plasma processing chamber 10. The DC power supply 32 includes a first DC generator 32a and a second DC generator 32b. In one embodiment, the first DC generator 32a is connected to at least one lower electrode and configured to generate a first DC signal. The generated first DC signal is applied to at least one lower electrode. In one embodiment, the second DC generator 32b is connected to at least one upper electrode and configured to generate a second DC signal. The generated second DC signal is applied to at least one upper electrode.

In various embodiments, the first and second DC signals may pulsate. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulses may have positive polarity or negative polarity. Further, the sequence of voltage pulses may include one or multiple positive polarity voltage pulses and one or multiple negative polarity voltage pulses in one cycle. The first and second DC generators 32a and 32b may be provided in addition to the RF power supply 31, or the first DC generator 32a may be provided instead of the second RF generator 31b.

The exhaust system 40 may be connected to a gas exhaust port 10e provided at the bottom portion of the plasma processing chamber 10, for example. The exhaust system 40 may include a pressure control valve and a vacuum pump. The pressure in the substrate processing space 10s is adjusted by the pressure control valve. The vacuum pump may include a turbomolecular pump, a dry pump, or a combination thereof.

In one embodiment, the exhaust system 40 includes an upper baffle plate 41 and a lower baffle plate 42. The upper baffle plate 41 and the lower baffle plate 42 have through-holes 43 and 44, respectively. The upper baffle plate 41 and the lower baffle plate 42 form a boundary between the substrate processing space 10s and the exhaust system 40.

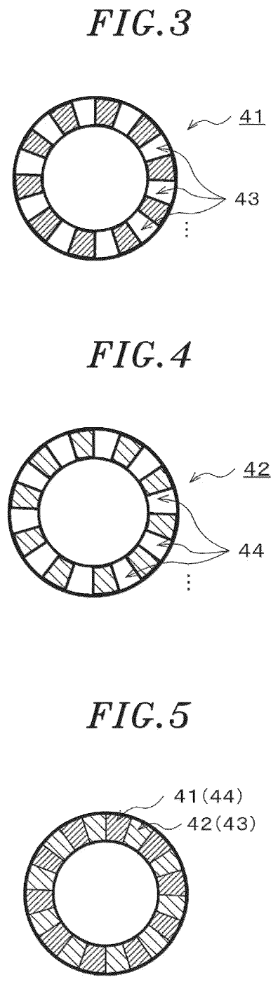

FIG. 3 is a plan view of the upper baffle plate 41 viewed from the top of the plasma processing chamber 10. As illustrated, the upper baffle plate 41 has the through-holes 43 in addition to the plate portions indicated by hatching. A gas can flow through the through-holes 43. Specifically, a gas flows from the substrate processing space 10s to the exhaust system 40 through the through-holes 43.

FIG. 4 is a plan view of the lower baffle plate 42 viewed from the top of the plasma processing chamber 10. As illustrated, the lower baffle plate 42 has the through-holes 44 in addition to the plate portions indicated by hatching. A gas can flow through the through-holes 44. Specifically, a gas flows from the substrate processing space 10s to the exhaust system 40 through the through-holes 44.

FIG. 5 is a plan view of the upper baffle plate 41 and the lower baffle plate 42, which is viewed from the top to show the arrangement relationship thereof. As illustrated, the upper baffle plate 41 and the lower baffle plate 42 are arranged such that the positions of the through-holes 43 and 44 are misaligned with each other. In the example shown in FIG. 5, the plate portions indicated by hatching in the upper baffle plate 41 overlap the through-holes 44 in the lower baffle plate 42, and the plate portions indicated by hatching in the lower baffle plate 42 overlap the through-holes 43 in the upper baffle plate 41.

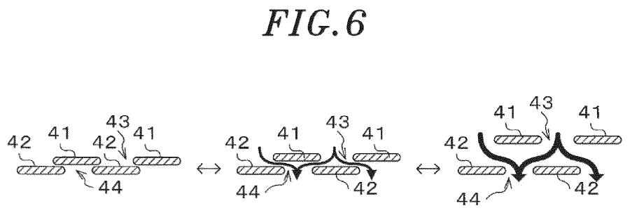

FIG. 6 is a side view of the upper baffle plate 41 and the lower baffle plate 42 viewed from the sidewall 10a of the chamber. In FIG. 6, the gas flow is indicated by thick arrows. Further, the relative magnitude of the gas flow is indicated by the thickness of the thick arrows. When at least one of the upper baffle plate 41 and the lower baffle plate 42 moves up and down and they become close to each other, the distance between the through-holes 43 and 44 is shortened, which suppresses the flow of gas flow through the through-holes 43 and 44. In addition to the above configuration, the gas flow may change by rotating at least one of the upper baffle plate 41 and the lower baffle plate 42 and changing the distance between the through-holes 43 and 44. In this configuration, the volume of the substrate processing space 10s can be limited by using the upper baffle plate 41 and the lower baffle plate 42, and even when the exhaust speed is increased, the exhaust operation can be performed in a state where the pressure in the substrate processing space 10s is uniform.

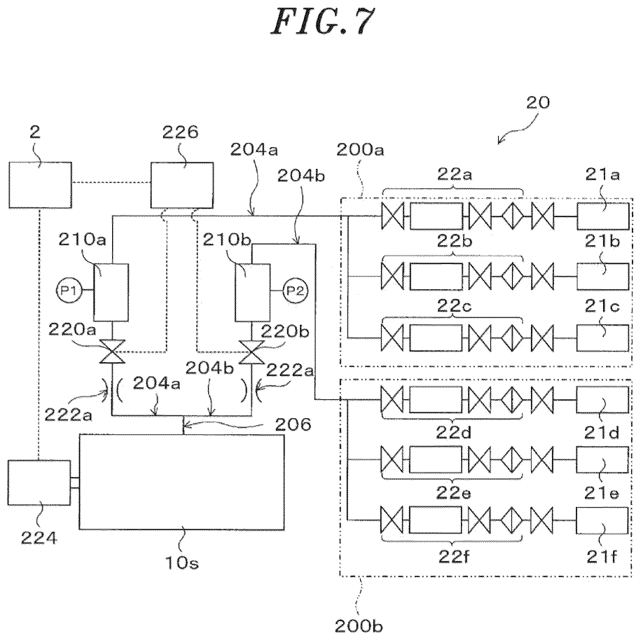

Next, the gas supply part 20 and the substrate processing space 10s according to the present embodiment will be described in detail with reference to FIG. 7. FIG. 7 is a schematic diagram showing an outline of the gas supply part 20 and the substrate processing space 10s according to the present, and the flow path that connects them.

In FIG. 7, the gas supply part 20 includes gas boxes 200a and 200b and a flow path. The gas box 200a includes gas sources 21a, 21b, and 21c and a plurality of flow rate controllers 22a, 22b, and 22c respectively corresponding thereto. The gas box 200b includes gas sources 21d, 21e, and 21f and a plurality of flow rate controllers 22d, 22e, and 22f respectively corresponding thereto. The flow paths include a plurality of first flow paths 204a and 204b and a second flow path 206. The downstream sides of the plurality of gas sources 21a to 21f are connected to the upstream sides of the plurality of flow rate controllers 22a to 22f corresponding thereto. Further, the downstream sides of the plurality of flow rate controllers 22a to 22f are connected to the first flow paths 204a, 204b. The downstream sides of the first flow paths 204a and 204b join the second flow path 206. The downstream of the second flow path 206 is connected to the substrate processing space 10s. The downstream of the second flow path 206 may be connected to a gas introducing part, and may be connected to the substrate processing space 10s via the shower head 13 described above. The gas box 200 is not limited to the illustrated configuration. For example, a gas box having a gas source that supplies a mixed gas in which a plurality of gas species are mixed in advance at a desired ratio may supply the mixed gas to one of the first flow paths 204a and 204b. Further, the combination or number of the gas source 21, the flow rate controller 22, and the first flow paths 204a and 204b is not limited to the illustrated configuration. For example, the number of the plurality of flow rate controllers 22 that join one of the first flow paths 204a and 204b, and the number of the corresponding gas sources 21 may be increased or decreased to a desired number. Alternatively, for example, a switchable configuration may be adopted, allowing a desired combination of the plurality of gas sources 21 to merge, and this configuration enables control of gas mixing at a desired ratio in one of the first flow paths 204a and 204b.

In one embodiment, the first flow paths 204a and 204b are provided with buffer tanks 210a and 210b, respectively. The buffer tanks 210a and 210b have pressure sensors P1 and P2 capable of measuring the pressure therein, respectively. The buffer tanks 210a and 210b may be configured such that the area (hereinafter, referred to as “flow path cross-sectional area”) of the cross section (hereinafter, referred to as “flow path cross-section”) perpendicular to the gas flow path direction is greater than the flow path cross-sectional area of the lines constituting the first flow paths 204a and 204b. In this case, the flow path cross-sectional areas of the buffer tanks 210a and 210b may be three times or more the flow path cross-sectional areas of the first flow paths 204a and 204b. Moreover, in this case, the lengths of the buffer tanks 210a and 210b in the flow path direction may be greater than or equal to the diameters of the flow path cross-sections of the buffer tanks 210a and 210b.

In one embodiment, the volume of the buffer tank 210a is sufficiently greater than the target value (volume value) of the supply amount of the mixed gas Gα in step ST12 for one pulse set to be described later, and the volume of the buffer tank 210b is sufficiently greater than the target value (volume value) of the supply amount of the mixed gas Gβ in step ST16 for one pulse set to be described later. In this case, the volumes of the buffer tanks 210a and 210b are preferably five times or more, and more preferably ten times or more the target values of the supply amounts of the mixed gases Gα and Gβ, respectively.

In another embodiment, the volumes of the buffer tanks 210a and 210b are variable. For example, a controllable piston is provided to change the volumes of the buffer tanks 210a and 210b to a desired volume.

In another embodiment, the temperatures of the buffer tanks 210a and 210b are variable. For example, a temperature control mechanism capable of controlling the temperature of the gas in the buffer tanks 210a and 210b is connected. In this case, the temperature control mechanism may be a heater for heating the gas in the buffer tanks 210a and 210b.

Pulse valves 220a and 220b are provided in the first flow paths 204a and 204b. Further, orifices 222a and 222b are provided at the downstream sides of the pulse valves 220a and 220b. The valve of which opening and closing can be instantly switched may be used as the pulse valves 220a and 220b. Specifically, although not particularly limited, it is preferable to use a valve that allows the opening and closing of the flow of the gas to be switched with a pulse interval of at least less than 50 ms. At the above speed, a gas can be supplied at a flow rate and switching speed with sufficient accuracy in the flow rate control using the pulse valves 220a and 220b which will be described later. Further, in this specification, the control of alternately repeating the opening and closing of the pulse valves 220a and 220b is referred to as “pulse control”. Further, in the pulse control, a single gas flow cycle which the pulse valves 220a and 220b are opened from the closed state and then closed again is referred to as “one pulse PL”.

The chamber sidewall 10a is provided with a chamber monitor 224 as a detector capable of detecting plasma emission or gas composition in the substrate processing space 10s. The chamber monitor 224 may be, e.g., an optical emission spectrometer (OES) capable of detecting plasma emission in the substrate processing space 10s from the chamber sidewall 10a. Further, the chamber monitor 224 may be a known detector capable of detecting the gas composition in the substrate processing space 10s from the chamber sidewall 10a. In one embodiment, the chamber monitor 224 transmits information on the detected plasma emission (including the emission amount or the emission intensity ratio) or gas composition (including gas existence amount or gas existence ratio, gas including by-products resulting from dissociation of gas components) to the controller 2. The controller 2 performs calculation based on the information, updates the target value of the gas supply amount, and transmits the target value to the controller 226. The controller 226 controls the pulse valves 220a and 220b based on the target value, and increases or decreases the flow rates in the pulse valves 220a and 220b.

Although the buffer tanks 210a and 210b are provided as preferred configurations in FIG. 7, they are not necessary, and the buffer tanks 210a and 210b may not be provided. In this case, for example, the lines constituting the first flow paths 204a and 204b may be partially expanded to have the same dimensions as those of the buffer tanks 210a and 210b. Further, although the second flow path 206 is provided, it is not necessary. In this case, the downstream sides of the first flow paths 204a and 204b may be directly connected to the gas introduction part, e.g., the shower head 13. Although the chamber monitor 224 is provided, it is not necessary.

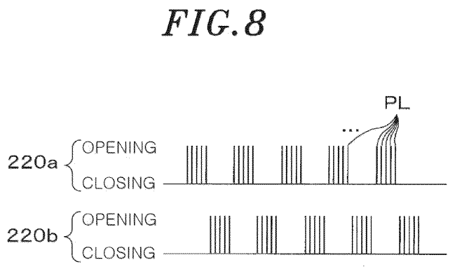

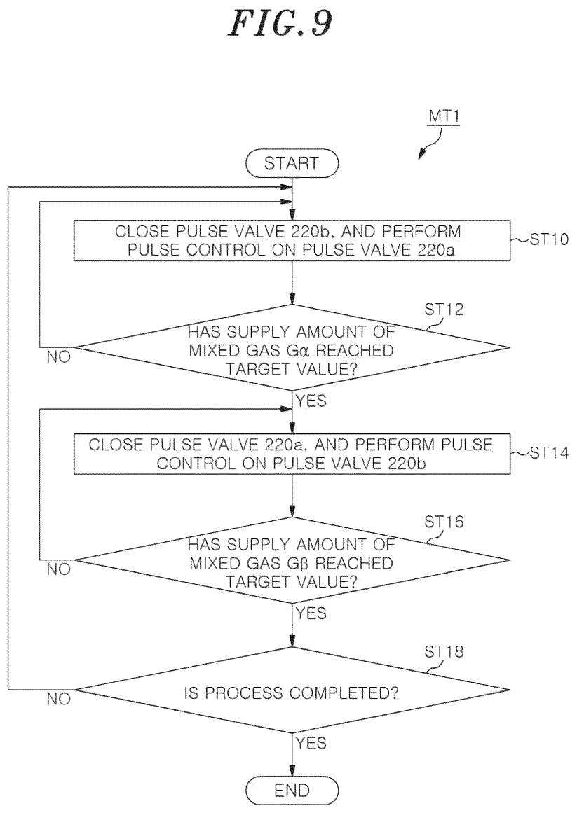

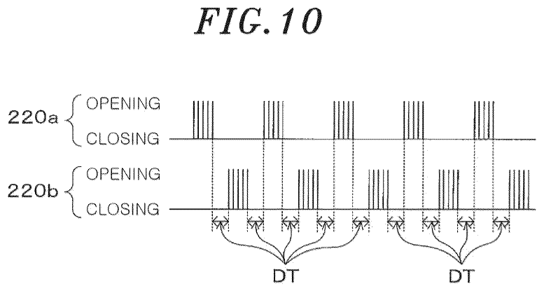

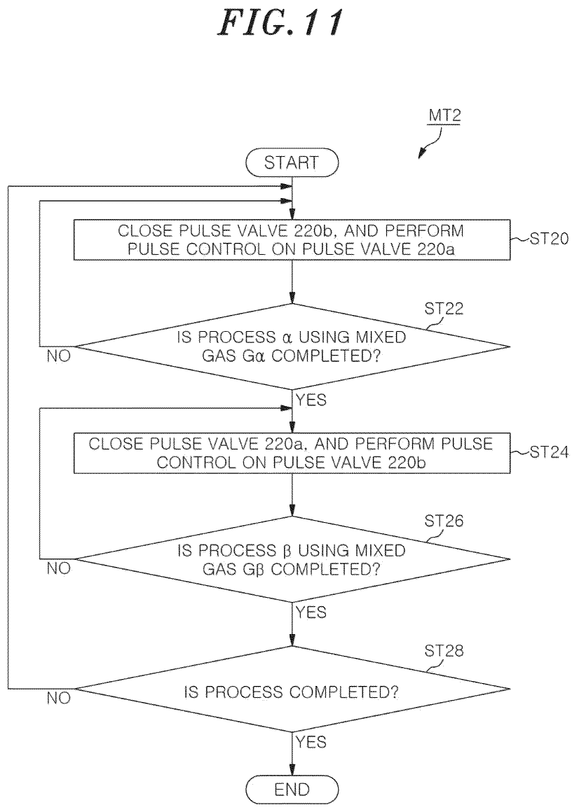

Next, a substrate processing method according to the present embodiment will be described with reference to FIGS. 8 to 11. FIG. 8 is an explanatory diagram of the opening and closing control of the pulse valve in a substrate processing method MT1 according to an embodiment. FIG. 9 is a flowchart schematically showing the substrate processing method MT1 according to an embodiment. FIG. 10 is an explanatory diagram schematically showing another example of the pulse control in the substrate processing method MT1 according to an embodiment. FIG. 11 is a flowchart schematically showing a substrate processing method MT2 according to another embodiment. The substrate processing methods MT1 and MT2 according to the present embodiment can be performed in the above-described plasma processing system, for example. In the substrate processing methods MT1 and MT2, the flow rate of the gas supplied to the substrate processing space 10s is controlled by the pulse control of the pulse valves 220a and 220b.

In the following description of the substrate processing methods MT1 and MT2, the case in which gas species a to c are supplied from the gas sources 21a to 21c to the first flow path 204a via the flow rate controllers 22a to 22c, and gas species d to f are supplied from the gas sources 21d to 21f to the first flow path 204b via the flow rate controllers 22d to 22f in the plasma processing system shown in FIG. 7 will be described. Further, the gas species a to f may be known gases used in processing such as etching or deposition, or may be known gases for diluting them. Prior to the execution of the substrate processing methods MT1 and MT2, the gas species a to c may be mixed in the first flow path 204a to become the mixed gas Gα, and then stored in the buffer tank 210a at a desired pressure. Further, the gas species d to f may be mixed in the first flow path 204b to become the mixed gas Gβ, and then stored in the buffer tank 210b at a desired pressure.

Hereinafter, a case in which gas supply is started in the substrate processing method MT1 according to the present embodiment, and in which the mixed gas Gα and the mixed gas Gβ are supplied separately and alternately, will be described. In FIGS. 8 and 9, first, the pulse control is started in the pulse valve 220a provided on the first flow path 204a. In the pulse control, the pulse valve 220a is repeatedly changed from a closed state to an open state and then changed to a closed state again. At this time period, the pulse valve 220b is maintained in a closed state (step ST10). Then, when the supply amount of the mixed gas Gα reaches a target value, the pulse control in the pulse valve 220a is terminated, and the supply of the mixed gas Gα is stopped (step ST12). Subsequently, the same pulse control is executed in the pulse valve 220b provided on the first flow path 204b, and the pulse valve 220a is maintained in a closed state during the pulse control (step ST14). Thereafter, when the supply amount of the mixed gas Gβ reaches the target value, the pulse control in the pulse valve 220b is terminated, and the supply of the mixed gas Gβ is stopped (step ST16). Then, the pulse control of the pulse valve 220a and the pulse valve 220b is alternately repeated, and it is continued until desired processing is completed (step ST18).

As shown in FIG. 10, when the pulse control of the mixed gas Gα is terminated and the control of the mixed gas Gβ is started, or vice versa (hereinafter, collectively referred to as “switching of mixed gas”), a delay time DT may be provided. In other words, for example, after the pulse control of the mixed gas Gα is terminated, when the delay time DT has elapsed, the control of the mixed gas Gβ may be started. In the case of switching the mixed gases, gases in the first flow paths 204a and 204b, the second flow path 206, and the substrate processing space 10s at the downstream sides of the pulse valves 220a and 220b are exhausted. Thus, the delay time DT is set as the time required until the exhaust is completed. Specifically, it is preferable to set the delay time DT to 10 ms to 1 s.

The target value of the supply amount of the mixed gas may be read from a value that is predetermined for each process. The start and end of the pulse control may be performed by causing the controller 2 to transmit a start command and an end command to the controller 226 based on the target value, and causing the controller 226 to control the pulse valves 220a and 220b.

The pulse control will be described in more detail. The duration of the pulse control and the number of pulses PL during the duration may be determined based on the flow rate per pulse PL and the target value of the supply amount of the mixed gas. Specifically, first, the number of pulses is determined such that the product of the flow rate per pulse PL and the number of pulses becomes the target value of the supply amount. For example, if the target value of the supply amount in the process is 100 and the flow rate of the mixed gas per pulse PL is 1, the supply amount of 100 can be supplied by setting the number of pulses to 100. After the number of pulses is determined, the duration of the pulse control can be determined such that the pulse control can be performed at a desired pulse interval. Further, the flow rate in one pulse PL may be measured in advance under process conditions.

In the case of switching the mixed gases, the method MT2 to be described below can be adopted in addition to the above-described method in which the supply of one mixed gas is switched to the supply of another mixed gas when the supply amount of one mixed gas reaches a target value. In other words, the state in the substrate processing space 10s is monitored by the chamber monitor 224, and the supply of the mixed gas is started or terminated based on the monitoring result. Specifically, the state in the substrate processing space 10s is monitored by the chamber monitor 224, such as an OES or the like, by detecting a ratio or amplitude of an emission wavelength of plasma emission of the gas, a wavelength correlation, or the like. In this case, first, the detection results detected by the chamber monitor 224 are transmitted to the controller 2. Next, the controller 2 determines whether or not a process α using the mixed gas Gα has been completed or whether or not a process β using the mixed gas Gβ has been completed based on the detection results. When it is determined that the process α or the process β has been completed, a command is transmitted to the controller 226 to execute the switching of the mixed gases, and the pulse valves 220a and 220b are controlled.

In FIG. 11, the monitoring using an OES and the control of the pulse valves 220a and 220b based on the monitoring results will be described as an example of the above-described monitoring of the gas state in the substrate processing space 10s. For example, a case in which the mixed gas Gα that is being supplied is an etching gas containing fluorine, and the mixed gas Gβ, that remains closed, is a deposition gas is considered. First, the pulse valve 220a is pulse-controlled to supply the mixed gas Gα (step ST20). At this time, plasma of the etching gas is produced in the substrate processing space 10s by the supply of the mixed gas Gα, and the etching of the substrate W as a target object progresses. During the etching, fluorine in the mixed gas Gα is consumed by the etching, so that the plasma emission amount of fluorine is small. On the other hand, when the etching approaches the end, the fluorine in the mixed gas Gα is no longer consumed by the etching, and the amount of the mixed gas Gα in the substrate processing space 10s increases. Accordingly, the plasma emission of fluorine increases, and the amount detected by the OES increases. In other words, when an increase in the amount of plasma emission of fluorine is detected in the OES, it may be determined that the etching approaches the end (step ST22). In the present embodiment, when the plasma emission amount is less than the threshold, the supply of the mixed gas Gα is continued, and when the plasma emission amount is greater than or equal to the threshold, it is determined that the etching is completed, and the supply of the mixed gas Gα is stopped. Accordingly, the supply of the remaining mixed gas Gα into the substrate processing space 10s can be suppressed. Thereafter, the pulse valve 220a is closed, and the pulse valve 220b is pulse-controlled to execute a next process (step ST24). The process β using the mixed gas Gβ is also monitored in the same manner, and it is determined whether or not the process β is completed (step ST26). When it is determined that the process β is completed, the processing returns to the pulse control of the pulse valve 220a, or the process is completed (step ST28). As the threshold value for the plasma emission amount, the wavelength emission amount that is an indicator of the progress of the process may be predetermined under the process conditions, stored in the storage part, and read out when the process is executed.

Although the plasma emission amount of fluorine in the etching gas is detected as the detection target in the above example, the present disclosure is not limited thereto, and the progress of the process may be determined by detecting the existence amount of the gas that is an indicator of the process of the process, or the gas ratio. The gas detected here includes products generated by dissociation of the gas components in addition to the gas components themselves. In this case, the threshold value may be predetermined for each gas as an indicator under the process conditions, stored in the memory part, and read out when the process is executed. In addition, although the plasma emission amount is monitored and compared with the threshold value in the above example, the present disclosure is not limited thereto. For example, the intensity ratio of light of multiple wavelengths detected by the OES may be monitored and compared with the threshold value to determine the progress of the etching. In this case, if the intensity ratio is less than the threshold value, the supply of the mixed gas Gα may be continued, and if the intensity ratio is greater than or equal to the threshold value, the supply of the mixed gas Gα may be stopped. Alternatively, if the intensity ratio is greater than or equal to the threshold value, the supply of the mixed gas Gα may be continued, and if the intensity ratio is less than the threshold value, the supply of the mixed gas Gα may be stopped. As the threshold value for the intensity ratio, the intensity ratio of the light of the wavelength that is an indicator of the progress of the process may be predetermined under the process condition, stored in the storage part, and read out when the process is executed.

Further, although an example in which the pulse control and the switching control are performed for two types of mixed gases Gα and Gβ has been described, the same control can be performed when three or more types of mixed gases flow on three or more first flow paths and are supplied to the substrate processing space 10s. In this case, while the pulse control for one mixed gas is being performed, the pulse valve for the flow of another mixed gas may be closed to stop the supply thereof. In addition, the delay time DT may be provided between the switching of mixed gases.

Next, the significance of the above-described configuration of the plasma processing apparatus 1 and the substrate processing methods MT1 and MT2 in the present disclosure will be described in detail.

As described in FIG. 12, in the conventional method, the configuration and method for switching two or more types of gases are used, the switching time is shortened by switching the path for supplying a gas to the substrate processing space PS and the path for exhausting a gas using the exhaust system ES. The conventional configuration has the following drawback in addition to the cost issue caused by constant disposal of a gas that is not supplied to the substrate processing space PS. In other words, in the conventional configuration, while one gas is being supplied, the supply valves VSR and VSL are maintained in an open state. In this state, the flow rates of the gases supplied through the supply valves VSR and VSL are limited to a certain value depending on the specifications of the supply valves VSR and VSL. Therefore, in order to supply a gas at a desired flow rate, it was necessary to provide the flow rate controllers FCR and FCL on the flow paths CR and CL. On the other hand, in the technique of the present disclosure, a gas to be supplied is supplied by pulse control using the pulse valves 220a and 220b. The case of supplying a gas by pulse control instead of supplying a gas in a state where the valves are opened has the following significance. In other words, it is possible to control a gas to be supplied at a desired flow rate by changing the density, number, and interval of the pulses PL, and the duration of the pulse control to desired values. In other words, in the pulse control of the present disclosure, the flow rate of the gas to be supplied to the substrate processing space 10s can be controlled to a desired value. In other words, in the gas supply part 20 of the present disclosure, it is not necessary to provide a flow rate controller for each mixed gas. Accordingly, the system size of the gas supply part to can be scaled down compared to that of the conventional configuration.

Next, the significance of the buffer tanks 210a and 210b and the orifices 222a and 222b, which are provided as preferred configurations in the present disclosure, will be described.

In the pulse control using the pulse valves 220a and 220b, the flow rate of the flowing gas is not constant, and may change periodically depending on the pulse control conditions. In this specification, such a periodic change in the flow rate is referred to as “flow rate pulsation.” The flow rate pulsation may occur at the upstream sides of the downstream sides of the pulse valves 220a and 220b as well as at the downstream sides thereof.

When the flow rate pulsation occurs, a load may be applied to structural members, or the measurement using various sensors such as a pressure sensor and the like may become unstable. It is known that the degree of influence of the flow rate pulsation depends on the volume of the flow path that is the space where the flow rate pulsation occurs. Specifically, as the volume of the flow path decreases, the influence of the flow rate pulsation increases, and as the volume of the flow path increases, the influence of the flow rate pulsation decreases. Therefore, in one embodiment of the present disclosure, the buffer tanks 210a and 210b are provided. In other words, the buffer tanks 210a and 210b have the function of expanding the volume of the space where the flow rate pulsation occurs and buffering the flow rate pulsation. In addition, the orifices 222a and 222b have the function of making the flow rate at the downstream sides thereof uniform. Due to the buffer tanks 210a and 210b, the magnitude of the flow rate pulsation can be reduced, and the influence thereof can be sufficiently suppressed. In order to enhance such effects, the buffer tanks 210a and 210b are preferably set such that the flow path cross-sectional areas thereof are three or more times the flow path cross-sectional areas of the first flow paths 204a and 204b, and the lengths of the buffer tanks 210a and 210b in the flow path direction are greater than or equal to the diameters of the flow path cross-sectional areas of the buffer tanks 210a and 210b. On the other hand, if the volumes of the buffer tanks 210a and 210b are excessively large, the time required to fill the buffer tanks 210a and 210b with a gas to reach a desired pressure increases. Further, the lines including the buffer tanks 210a and 210b are evacuated at the end of the process, so that the gas is wasted. Therefore, it is not preferable that the buffer tanks 210a and 210b are unnecessarily large.

The inventors have found through careful study that when the buffer tank is provided, it is important for more precise control of the gas supply amount that the pressure in the buffer tank during the pulse control is maintained substantially constant without variation from the start of the supply of the mixed gas until the supply of the mixed gas is stopped when the supply amount of the mixed gas reaches the target value.

In the following description, a series of pulse controls during the duration from the start of the supply of the mixed gas until the supply of the mixed gas is completed when the supply amount of the mixed gas reaches the target value is referred to as “one pulse set.” A series of control from the start of the pulse control of the pulse valve 220a in step ST10 to the closing of the pulse valve 220a in step ST14 is an example of one pulse set.

If the mixed gas supplied in the present disclosure is considered as an ideal gas, P=nRT/V is established from the state equation of gas, where P is the pressure in the buffer tank, V is the volume of the buffer tank, n is the amount of mixed gas supplied (amount of substance) in one pulse set, R is the gas constant, and T is the absolute temperature of the mixed gas.

From this viewpoint, as described above, the volume of the buffer tank in one embodiment is sufficiently greater than the target value (volume value) of the supply amount of the mixed gas in one pulse set. During the gas supply in the pulse set, the mixed gas in the buffer tank is reduced by a maximum of a supply amount n of the mixed gas. At this time, the volume V of the buffer tank is sufficiently large for the gas volume (i.e., function of the supply amount n) reduced in the buffer tank, so that the pressure P in the buffer tank can be constant. The state in which the pressure P is constant includes a state in which the pressure P does not become lower than a desired threshold value to be described below.

Further, in another embodiment, the volume of the buffer tank is variable. During the gas supply in the pulse set, the mixed gas in the buffer tank is reduced by a maximum of the supply amount n of the mixed gas. At this time, by controlling the volume of the buffer tank to be reduced by the volume of the mixed gas reduced in the buffer tank, the ratio n/V of the supply amount n and the volume V can be maintained substantially constant, and the pressure P in the buffer tank can be maintained constant, for example.

Further, in another embodiment, the temperature of the buffer tank is variable. During the gas supply in the pulse set, the mixed gas in the buffer tank is reduced by a maximum of the supply amount n of the mixed gas. However, by increasing the absolute temperature T of the gas by the amount of the mixed gas that is reduced in the buffer tank, the product nT of the supply amount n and the absolute temperature T can be maintained substantially constant, and the pressure P in the buffer tank can be maintained constant, for example.

Here, it is more preferable that the pressure P in the buffer tank is maintained substantially constant during the duration of the pulse control from the start to the end of one pulse set. However, in one embodiment, the pressure P in the buffer tank may be reduced to a value greater than a desired threshold value. For example, such a threshold value is 80% of the pressure P at the start of the pulse set.

Further, in FIG. 7, the buffer tanks 210a and 210b are provided in the first flow paths 204a and 204b on the upstream sides of the pulse valves 220a and 220b. However, the present disclosure is not limited thereto. For example, the buffer tanks 210a and 210b may be provided in the first flow paths 204a and 204b on the downstream sides of the pulse valves 220a and 220b. Also in this case, the effect of reducing the influence of the flow rate pulsation is achieved. Since, however, the first flow paths 204a and 204b on the downstream sides of the pulse valves 220a and 220b are exhausted during the switching of mixed gases, the exhaust time increase if the buffer tanks 210a and 210b are large. From this viewpoint, it is more preferable to provide the buffer tanks 210a and 210b in the first flow paths 204a and 204b on the upstream sides of the pulse valves 220a and 220b.

Next, the significance of the chamber monitor 224 provided as a preferred configuration in the present disclosure will be described.

In the process such as deposition or etching, the required amount of a deposition gas or an etching gas depends on the conditions of the substrate W to be processed or the conditions of the apparatus. The conditions of the substrate W may include a surface area or surface property of the substrate W. Further, the conditions of the apparatus may include, e.g., a degree of wear of consumable parts, the existence amount of processing residue (deposits) in the chamber or in the line. Therefore, it is preferable to change the gas supply amount depending on the substrate conditions or the conditions of the apparatus. In the substrate processing method MT2, by monitoring the state in the substrate processing space 10s using the chamber monitor 224, it is possible to switch mixed gas when the process is actually terminated.

Next, the significance of providing the delay time DT and the exhaust system 40 as described above in the present disclosure will be described.

When the mixed gas Gα and the mixed gas Gβ are supplied separately and alternately as described above, both the mixed gas Gα and the mixed gas Gβ flow in the second flow path 206 and the substrate processing space 10s on the downstream side of the pulse valve 220a or the pulse valve 220b, so that these gases may be mixed unintentionally. On the other hand, in the present embodiment, due to the delay time DT, it is possible to control the supply of either the mixed gas Gα or the mixed gas Gβ to be started when the supply of another mixed gas is completed and the exhaust of the second flow path 206 and the substrate processing space 10s is completed.

From the viewpoint of throughput, it is preferable to minimize the delay time DT as long as the mixed gases are not mixed. In order to shorten the delay time DT, it is preferable to sufficiently increase the exhaust speed of the substrate processing space 10s. When the high-speed exhaust operation is performed, it is preferable to improve the uniformity of the pressure in the space of the exhaust system 40 and the substrate processing space 10s. As a specific example of the exhaust system 40, it is preferable to adopt a configuration including the upper baffle plate 41 and the lower baffle plate 42 shown in FIGS. 2 to 6.

It should be noted that the above-described embodiments are illustrative in all respects and are not restrictive. The above-described embodiments may be omitted, replaced, or changed in various forms without departing from the scope of the appended claims, the configuration examples included in the technical scope of the present disclosure to be described later and the gist thereof. For example, the components of the above-described embodiments can be randomly combined. The effects of the components for arbitrary combination can be obtained from the corresponding arbitrary combination, other effects apparent to those skilled in the art can also be obtained.

The effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

The following configurations are also included in the technical scope of the present disclosure.

(1) A substrate processing method for processing a substrate by supplying a gas from a gas supply part to a substrate processing space in a substrate processing apparatus,
wherein the gas supply part includes a plurality of gas sources, a flow path that allows the gas to flow from the plurality of gas sources to the substrate processing space, a valve provided in the flow path to switch between opening and closing the flow of the gas, and a buffer tank provided in the flow path,
pulse control is performed to pulse the flow of the gas by alternately repeating the opening and closing of the flow of the gas in the valve, and
in the pulse control, a duration of the pulse control and a number of times of opening the flow of the gas during the duration are controlled to control the flow rate of the gas.

(2) The substrate processing method of (1), wherein the flow path includes a plurality of first flow paths corresponding to the plurality of gas sources, and a second flow path where the plurality of first flow paths join,
the valve is provided in each of the plurality of first flow paths, and
the pulse control is performed on the valve provided in one of the first flow paths to supply the gas to the substrate processing space and close another valve provided in another first flow path.

(3) The substrate processing method of (2), wherein two or more gas sources among the plurality of gas sources correspond to one of the plurality of first flow paths, and
the gases are supplied from the plurality of gas sources and mixed in the first flow path.

(4) The substrate processing method of (2) or (3), comprising:
executing the pulse control in one valve;
closing the flow of the gas in the valve; and
executing the pulse control in another valve after a delay time of 10 ms to 1 s has elapsed.

(5) The substrate processing method of any one of (1) to (4), wherein the substrate processing apparatus includes a detector configured to detect plasma emission in the substrate processing space, and
when the gas supplied to the substrate processing space by the pulse control is an etching gas, during the pulse control, the pulse control is continued if the emission amount of the plasma emission is less than a threshold value, and the pulse control is terminated if the emission amount becomes greater than or equal to the threshold value.

(6) The substrate processing method of any one of (1) to (5), wherein the substrate processing apparatus includes a detector configured to detect gas components in the substrate processing space, and
during the pulse control, if the existence amount of the gas components supplied to the substrate processing space by the pulse control is greater than or equal to a threshold value, the pulse control is continued, and if the existence amount of the gas components is less than the threshold value, the pulse control is terminated.

(7) The substrate processing method of (2) or (3), wherein the substrate processing apparatus includes the buffer tank in each of the plurality of first flow paths,
wherein a flow path cross-sectional area of the buffer tank is three times or more a flow path cross-sectional area of the first flow path in which the buffer tank is provided, and
a length of the buffer tank in the flow path direction is greater than or equal to a diameter of the flow path cross-sectional area of the buffer tank.

(8) The substrate processing method of any one of (1) to (7), wherein the substrate processing apparatus includes an upper electrode, and
the gas is supplied from the gas supply part to a vicinity of a center of the upper electrode, diffused in a diffusion space provided in the upper electrode, and introduced into the substrate processing space.

(9) A substrate processing apparatus comprising:
a processing chamber where a substrate processing space is formed;
a gas supply part configured to supply a gas to the substrate processing space; and
a controller;
wherein the gas supply part includes a plurality of gas sources, a flow path that allows a gas to flow from the plurality of gas sources to the substrate processing space, a valve provided in the flow path to switch between opening and closing the flow of the gas, and a buffer tank provided in the flow path, and
the controller is configured to execute:
performing pulse control to pulse the flow of the gas by alternately repeating opening and closing of the flow of the gas in the valve when the gas is supplied from the gas supply part to the substrate processing space to process the substrate; and
in the pulse control, controlling the flow rate of the gas by controlling a duration of the pulse control and a number of times of opening the flow of the gas during the duration.

(10) The substrate processing apparatus of (9), wherein the flow path includes a plurality of first flow paths provided to correspond to the plurality of gas sources and a second flow path where the plurality of first flow paths join,
the valve is provided in each of the plurality of first flow paths, and
the controller is further configured to execute:
performing the pulse control on the valve provided in one of the first flow paths to supply the gas to the substrate processing space and close another valve provided in another first flow path.

(11) The substrate processing apparatus of (10), wherein two or more gas sources among the plurality of gas sources correspond to one of the plurality of first flow paths, and
the controller is further configured to execute:
supplying the plurality of gases from the plurality of gas sources and mixing the gases in the first flow path.

(12) The substrate processing apparatus of (10) or (11), wherein the controller is further configured to execute:
executing the pulse control in one valve;
closing the flow of the gas in the valve; and
executing the pulse control in another valve after a delay time of 10 ms to 1 s has elapsed.

(13) The substrate processing apparatus of any one of (9) to (12), further comprising:
a detector configured to detect plasma emission in the substrate processing space,
wherein the controller is further configured to execute:
when the gas supplied to the substrate processing space by the pulse control is an etching gas, during the pulse control, continuing the pulse control if the emission amount of the plasma emission is less than a threshold value and terminating the pulse control if the emission amount is greater than or equal to the threshold value.

(14) The substrate processing apparatus of any one of (9) to (13), further comprising:
a detector configured to detect gas components in the substrate processing space,
wherein the controller is further configured to execute:
during the pulse control, continuing the pulse control when the existence amount of the gas components supplied to the substrate processing space by the pulse control is greater than or equal to a threshold value and terminating the pulse control if the existence amount of the gas components is than the threshold value.

(15) The substrate processing apparatus of (10) or (11), further comprising:
the buffer tank in each of the first flow paths,
wherein a flow path cross-sectional area of the buffer tank is three times or more a flow path cross-sectional area of the first flow path in which the buffer tank is provided, and
a length of the buffer tank in the flow path direction is greater than or equal to a diameter of the flow path cross-sectional area of the buffer tank.

(16) The substrate processing apparatus of any one of (9) to (15), further comprising:
an upper electrode,
wherein the controller is further configured to execute:
supplying the gas from the gas supply part to a vicinity of a center of the upper electrode, diffusing in a diffusion space provided in the upper electrode, and introducing the gas into the substrate processing space.

1. A substrate processing method for processing a substrate by supplying a gas from a gas supply part to a substrate processing space in a substrate processing apparatus,
wherein the gas supply part includes a plurality of gas sources, a flow path that allows the gas to flow from the plurality of gas sources to the substrate processing space, a valve provided in the flow path to switch between opening and closing the flow of the gas, and a buffer tank provided in the flow path,
pulse control is performed to pulse the flow of the gas by alternately repeating the opening and closing of the flow of the gas in the valve, and
in the pulse control, a duration of the pulse control and a number of times of opening the flow of the gas during the duration are controlled to control the flow rate of the gas.

2. The substrate processing method of claim 1, wherein the flow path includes a plurality of first flow paths corresponding to the plurality of gas sources, and a second flow path where the plurality of first flow paths join,
the valve is provided in each of the plurality of first flow paths, and
the pulse control is performed on the valve provided in one of the first flow paths to supply the gas to the substrate processing space and close another valve provided in another first flow path.

3. The substrate processing method of claim 2, wherein two or more gas sources among the plurality of gas sources correspond to one of the plurality of first flow paths, and
the gases are supplied from the plurality of gas sources and mixed in the first flow path.

4. The substrate processing method of claim 2, comprising:
executing the pulse control in one valve;
closing the flow of the gas in the valve; and
executing the pulse control in another valve after a delay time of 10 ms to 1 s has elapsed.

5. The substrate processing method of claim 1, wherein the substrate processing apparatus includes a detector configured to detect plasma emission in the substrate processing space, and
when the gas supplied to the substrate processing space by the pulse control is an etching gas, during the pulse control, the pulse control is continued if the emission amount of the plasma emission is less than a threshold value, and the pulse control is terminated if the emission amount becomes greater than or equal to the threshold value.

6. The substrate processing method of claim 1, wherein the substrate processing apparatus includes a detector configured to detect gas components in the substrate processing space, and
during the pulse control, if the existence amount of the gas components supplied to the substrate processing space by the pulse control is greater than or equal to a threshold value, the pulse control is continued, and if the existence amount of the gas components is less than the threshold value, the pulse control is terminated.

7. The substrate processing method of claim 2, wherein the substrate processing apparatus includes the buffer tank in each of the plurality of first flow paths,
wherein a flow path cross-sectional area of the buffer tank is three times or more a flow path cross-sectional area of the first flow path in which the buffer tank is provided, and
a length of the buffer tank in the flow path direction is greater than or equal to a diameter of the flow path cross-sectional area of the buffer tank.

8. The substrate processing method of claim 1, wherein the buffer tank is configured such that a volume of the buffer tank is variable, and the volume of the buffer tank is reduced to maintain a constant pressure in the buffer tank during the duration of the pulse control.

9. The substrate processing method of claim 1, wherein the buffer tank is configured such that a gas temperature in the buffer tank is adjustable, and the gas temperature in the buffer tank is increased to maintain a constant pressure in the buffer tank during the duration of the pulse control.

10. The substrate processing method of claim 1, wherein the substrate processing apparatus includes an upper electrode, and
the gas is supplied from the gas supply part to a vicinity of a center of the upper electrode, diffused in a diffusion space provided in the upper electrode, and introduced into the substrate processing space.

11. A substrate processing apparatus comprising:
a processing chamber where a substrate processing space is formed;
a gas supply part configured to supply a gas to the substrate processing space; and
a controller;
wherein the gas supply part includes a plurality of gas sources, a flow path that allows a gas to flow from the plurality of gas sources to the substrate processing space, a valve provided in the flow path to switch between opening and closing the flow of the gas, and a buffer tank provided in the flow path, and
the controller is configured to execute:
performing pulse control to pulse the flow of the gas by alternately repeating opening and closing of the flow of the gas in the valve when the gas is supplied from the gas supply part to the substrate processing space to process the substrate; and
in the pulse control, controlling the flow rate of the gas by controlling a duration of the pulse control and a number of times of opening the flow of the gas during the duration.

12. The substrate processing apparatus of claim 11, wherein the flow path includes a plurality of first flow paths provided to correspond to the plurality of gas sources and a second flow path where the plurality of first flow paths join,
the valve is provided in each of the plurality of first flow paths, and
the controller is further configured to execute:
performing the pulse control on the valve provided in one of the first flow paths to supply the gas to the substrate processing space and close another valve provided in another first flow path.

13. The substrate processing apparatus of claim 12, wherein two or more gas sources among the plurality of gas sources correspond to one of the plurality of first flow paths, and
the controller is further configured to execute:
supplying the plurality of gases from the plurality of gas sources and mixing the gases in the first flow path.

14. The substrate processing apparatus of claim 11, wherein the controller is further configured to execute:
executing the pulse control in one valve;
closing the flow of the gas in the valve; and
executing the pulse control in another valve after a delay time of 10 ms to 1 s has elapsed.

15. The substrate processing apparatus of claim 11, further comprising:
a detector configured to detect plasma emission in the substrate processing space,
wherein the controller is further configured to execute:
when the gas supplied to the substrate processing space by the pulse control is an etching gas, during the pulse control, continuing the pulse control if the emission amount of the plasma emission is less than a threshold value and terminating the pulse control if the emission amount is greater than or equal to the threshold value.

16. The substrate processing apparatus of claim 11, further comprising:
a detector configured to detect gas components in the substrate processing space,
wherein the controller is further configured to execute:
during the pulse control, continuing the pulse control when the existence amount of the gas components supplied to the substrate processing space by the pulse control is greater than or equal to a threshold value and terminating the pulse control if the existence amount of the gas components is than the threshold value.

17. The substrate processing apparatus of claim 12, further comprising:
the buffer tank in each of the first flow paths,
wherein a flow path cross-sectional area of the buffer tank is three times or more a flow path cross-sectional area of the first flow path in which the buffer tank is provided, and
a length of the buffer tank in the flow path direction is greater than or equal to a diameter of the flow path cross-sectional area of the buffer tank.

18. The substrate processing apparatus of claim 11, wherein the buffer tank is configured such that a volume of the buffer tank is variable, and
the controller is further configured to execute:
reducing the volume of the buffer tank to maintain a constant pressure in the buffer tank during the duration of the pulse control.

19. The substrate processing apparatus of claim 11, wherein the buffer tank is configured such that a gas temperature in the buffer tank is adjustable, and
the controller is further configured to execute:
increasing the gas temperature in the buffer tank to maintain a constant pressure in the buffer tank during the duration of the pulse control.

20. The substrate processing apparatus of claim 11, further comprising:
an upper electrode,
wherein the controller is further configured to execute:
supplying the gas from the gas supply part to a vicinity of a center of the upper electrode, diffusing in a diffusion space provided in the upper electrode, and introducing the gas into the substrate processing space.
